(19) United States
(12) Patent Application Publication
(10) Pub. No.: US 2004/0224500 A1
(43) Pub. Date: Nov. 11, 2004

(54) Method of forming metal line of semiconductor device

(76) Inventor: Ihl Hyun Cho, Daejeon-Shi (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/748,721

(22) Filed: Dec. 30, 2003

(30) Foreign Application Priority Data
May 9, 2003 (KR) 2003-29258

(51) Int. Cl. H01L 21/4763

(52) U.S. Cl. 438/643; 438/687

(57) ABSTRACT

Provided is a method of forming a metal line of a semiconductor device, comprising the steps of forming an interlayer insulating film on a semiconductor substrate, forming a metal line shaped pattern by etching the interlayer insulating film, forming a diffusion stopper film in conformity with the whole surface of a resultant object in which the metal line shaped pattern is formed, forming a copper film on the diffusion stopper film, forming a copper metal line by chemically and mechanically polishing the copper film and the diffusion stopper film above the interlayer insulating film, attaching a titanium metal or a ruthenium metal to only the copper metal line selectively, and annealing the attached titanium metal or ruthenium metal.

### BACKGROUND

1. Field of the Invention

The present invention relates to a method for manufacturing a semiconductor device and, more particularly, to a method for forming a metal line of a semiconductor device.

2. Discussion of Related Art

With increase of integration degree and multilayer of wiring structure, more copper (Cu) than aluminum (Al) is plentifully used as a metal line and a damascene process is mainly used for forming a metal line.

The damascene process is a technology of forming a trench by performing a photo lithography process and an etching process on an insulating film, filling such trench with a conductive material such as copper, and removing the conductive material except for a portion to be used for an wiring by using a chemical mechanical polishing, etc., and thus forming a line in the shape of the trench which was formed firstly.

In general, the damascene process is performed through following steps. First, a first interlayer insulating film is formed on a semiconductor substrate, and a contact hole is formed to open a conductive region below the first interlayer insulating film and tungsten is deposited thereon. Then, a contact plug is formed by using a chemical and mechanical polishing, the contact plug having a shape of buried tungsten in the contact hole. Subsequently, a second interlayer insulating film is formed over the whole surface of substrate with the contact plug and a trench is formed to open the contact plug in order to form a metal line. Next, a TaN film is deposited to use as a diffusion stopper film, and then copper seed layer is formed. Then, copper film is buried in the trench using an electroplating, and a metal line is formed by removing a barrier film and the copper film above the second interlayer insulating film using a chemical and mechanical polishing. Subsequently, silicon nitride film is formed to use for a capping film.

However, it has been known that an interface between the copper and the capping films is weak for electro-migration. Accordingly, it has also been known that an upper surface, i.e., the capping film has higher diffusivity of the copper, because adhesion of the interface between the copper and the capping films is worse than that of an interface between the copper and the diffusion stopper films.

### SUMMARY OF THE INVENTION

The present invention is directed to a method of forming a metal line capable of securing reliability of the metal line by selectively forming titanium or ruthenium metals, which can stop diffusion of copper selectively on an interface between a copper metal line and a capping film that is weak to electro-migration.

According to a preferred embodiment of the present invention, there is provided a method of forming a metal line of a semiconductor device, comprising the steps of: forming an interlayer insulating film on a semiconductor substrate; forming a metal line shaped pattern by etching the interlayer insulating film; forming a diffusion stopper film in conformity with the whole surface of a resultant material in which the metal line shaped pattern is formed; forming a copper film on the diffusion stopper film; forming a copper metal line by chemically and mechanically polishing the copper film and the diffusion stopper film above the interlayer insulating film; attaching a titanium metal or a ruthenium metal to only the copper metal line selectively; and annealing the attached titanium metal or ruthenium metal.

### BRIEF DESCRIPTION OF THE DRAWINGS

The accompanying drawings, which are incorporated in and constitute a part of the specification, illustrate an embodiment of the invention, and, together with the description, serve to explain the principles of the invention:

FIGS. 1 to 4 are sectional views for explaining a method of forming metal line of a semiconductor device according to the preferred first embodiment of the present invention.

FIGS. 5 to 8 are sectional views for explaining a method of forming metal line of a semiconductor device according to the preferred second embodiment of the present invention.

### DETAILED DESCRIPTION OF PREFERRED EMBODIMENTS

Hereinafter, the preferred embodiments according to the present invention will be described in detail with reference to the accompanying drawings. But, it should be understood that following embodiments are provided to give so full detail of the present invention, thereby enabling the ordinary skilled in the art to understand the present invention, and various modifications can be made, and the present invention is not limited to embodiments described below. In following description, although a layer is described to be placed on another layer, the layer may be placed right on another layer or be placed above another layer with a third layer interposed there between. In addition, thickness or size of each layer in the accompanying drawings is exaggerated for convenience and clearness of explanation. The same numeral in the drawings denotes the same element.

A method that electro-migration can be decreased by attaching titanium or ruthenium on a surface of only the opened copper except for the interlayer insulating film will be described.

First, a method wherein ruthenium is selectively formed on only a surface of copper using electroless metal deposition will be described. Copper metal film is dipped into a ruthenium chloride (RuCl₃) solution, and thus ruthenium (Ru) metal is selectively formed on the surface of the copper as a following equation 1.

Cu+Ru²⁺→Cu²⁺+Ru [Reaction equation 1]

Ruthenium (Ru) cluster or Ruthenium (Ru) nano-metallic particles are deposited on only the surface of the copper and do not adhere to an interlayer insulating film.

Hereinafter, a method wherein titanium (Ti) metal is selectively formed on a surface of copper using an electroless reduction method will be described. Copper metal film is dipped into a solution containing titanium chloride (TiCl₄) and hypo-phosphorous acid (H₃PO₂), and thus titanium (Ti) metal is selectively formed on the surface the copper as a following equation 2.

4H₃PO₂⁻+Ti⁴⁺+H₂O→Ti+2HPO₃²⁻+3H₂+4H⁺ [Reaction equation 2]

Herein, the hypo-phosphorous acid (H₃PO₂) functions as a reducing agent for reducing the titanium (Ti).

Hereinafter, the preferred embodiments of the present invention will be described in detail with reference to the accompanying drawings.

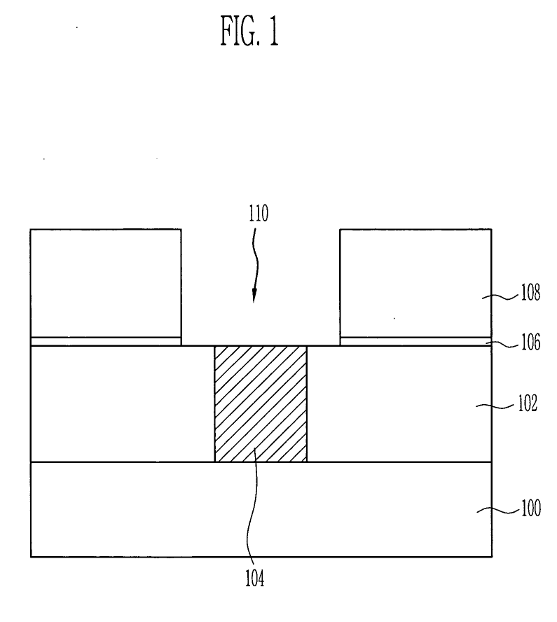

FIGS. 1 to 4 are sectional views for explaining a method of forming metal line of a semiconductor device according to the preferred first embodiment of the present invention.

Refer to FIG. 1, a first interlayer insulating film 102 is formed on a semiconductor substrate 100 on which a predetermined conductive layer (not shown) was formed. The conductive layer may be an impurities doped region or a metal line layer formed on the semiconductor substrate 100. It is desirable that the first interlayer insulating film 102 is formed of a material film having a lower dielectric index, such as an SiOC film, a phosphorous silicate glass (PSG) film, a boron phosphorous silicate glass (BPSG) film, an undoped silicate glass (USG) film, a fluorine doped silicate glass (FSG) film, a high density plasma (HDP) film, a plasma enhanced-tetra ethyl ortho silicate (PE-TEOS) film, or a spin on (glass SOG) film.

Subsequently, a contact hole is formed by etching the first interlayer insulating film 102 using a photolithography process and an etching process, and then the contact hole is filled with a conductive material to form a contact plug 104. As the conductive material, aluminum (Al) film, tungsten (W) film, copper (Cu) film, etc., may be used.

An etching stopper film 106 is formed in conformity with the whole surface of a resultant object in which the contact plug 104 is formed. It is desirable that the etching stopper film 106 is formed of a material having higher etching selectivity than that of a second interlayer insulating film 108 to be formed thereon subsequently, such as a silicon nitride film (Si₃N₄) or a silicon carbide film (SiC).

Next, the second interlayer insulating film 108 is formed on the etching stopper film 106. It is desirable that the second interlayer insulating film is formed of a material film having a lower dielectric index, such as an SiOC film, a PSG film, a BPSG film, an USG film, an FSG film, an HDP film, a PE-TEOS film, or an SOG film.

Subsequently, a trench 110, in which a metal line is to be formed, is formed by etching the second interlayer insulating film 108 and the etching stopper film 106 using a photolithography process and an etching process.

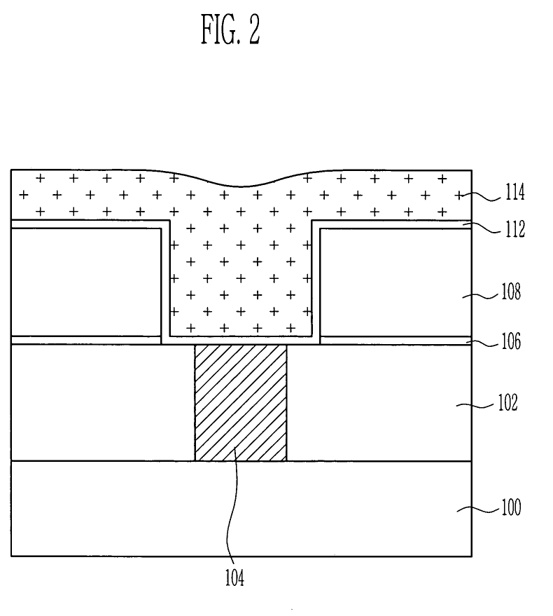

Refer to FIG. 2, a diffusion stopper film 112 is formed in conformity with the whole surface of a resultant object in which the trench 110 is formed. It is possible to form the diffusion stopper film 112 out of a material film which has better adhesion to the first interlayer insulating film 102 and a metal film 114 and is capable of stopping diffusion of the metal film 114, such as a Ti film, TiN film, etc. It is desirable that the diffusion stopper film 112 is formed to the thickness of 100 to 300 Å by using a chemical vapor deposition (CVD) method.

A metal seed layer (not shown) is formed on the diffusion stopper film 112, and then the metal film 114 is formed using an electroplating. The metal film 114 may be formed of a copper (Cu) film.

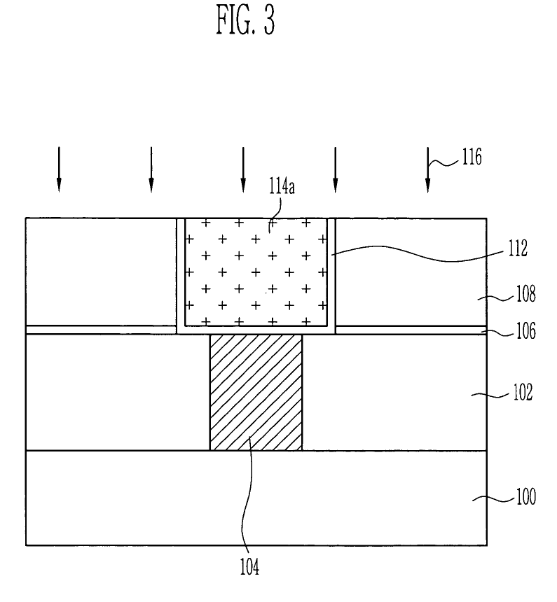

Refer to FIG. 3, a metal line 114a is formed by chemically and mechanically polishing the metal film 114. It is desirable that the chemical and mechanical polishing process is performed until the second interlayer insulating film 108 is exposed. The metal film 114 and the diffusion stopper film 112 on the top side of the second interlayer insulating film 108 are removed.

Then, as described above, an electroless electroplating 116 is performed using a titanium chloride (TiCl₄) solution or a ruthenium chloride (RuCl₃) solution. Namely, ruthenium (Ru) metal or titanium (Ti) metal is selectively formed on a surface of the copper (Cu) metal line 114a by dipping the copper (Cu) metal line into a ruthenium chloride solution or dipping the copper (Cu) metal line into a solution containing titanium chloride (TiCl₄) and hypo-phosphorous acid (H₃PO₂).

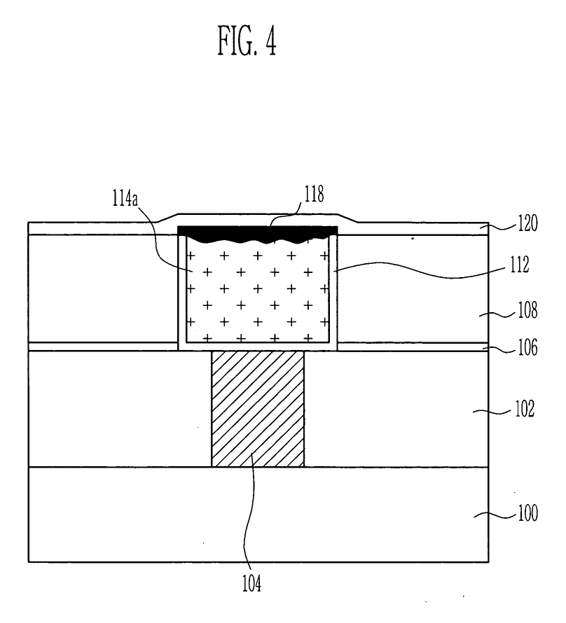

Refer to FIG. 4, titanium (Ti) or ruthenium (Ru) metals 118 is selectively formed on the metal film, e.g., only a surface of the copper (Cu) by the electroless electroplating. As a result, it is possible to improve reliability of the copper metal line by selectively attaching titanium (Ti) or ruthenium (Ru) on only the exposed surface of the copper on which a chemical and mechanical polishing process was performed, and thus decreasing electro-migration. Ti/Cu or Ru/Cu layers are formed by coating a surface of the copper (Cu) with titanium (Ti) or ruthenium (Ru), such that resistance to electro-migration can be improved.

Titanium (Ti) or Ruthenium (Ru) metals 118 is selectively formed on the metal film 114a, and then an annealing process is performed under an atmosphere containing nitrogen (N₂), hydrogen (H₂), or argon (Ar) gases, at a temperature of 200 to 400° C., and for 1 to 3 hours.

A capping film 120 is formed on the whole surface of a resultant material in which titanium (Ti) or Ruthenium (Ru) metals 118 is selectively formed. The capping film 120 is formed of silicon nitride film (Si₃N₄) or silicon carbide film (SiC).

Next, the preferred second embodiment of the present invention will be described in detail with reference to the accompanying drawings.

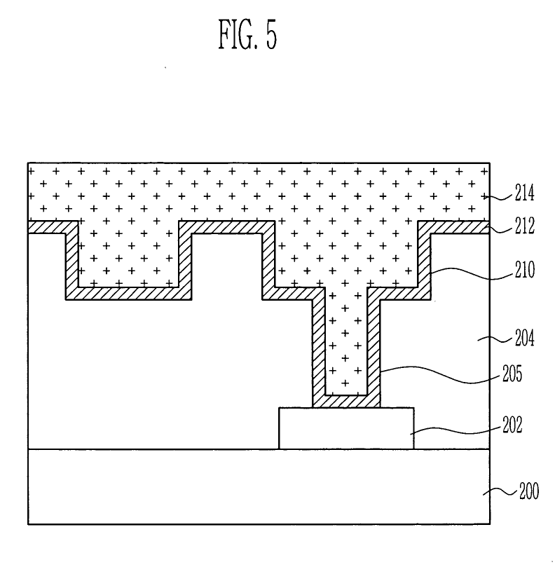

FIGS. 5 to 8 are sectional views for explaining a method of forming metal line of a semiconductor device according to the preferred second embodiment of the present invention.

Refer to FIG. 5, a conductive layer 202 is formed on a semiconductor substrate 200. The conductive layer may be a metal line formed on the semiconductor substrate 200 or an active region formed in the semiconductor substrate 200, such as source/drain. An interlayer insulating film 204 is formed on the semiconductor substrate 200 on which the conductive layer 202 was formed. It is desirable that the interlayer insulating film 204 is formed of a material film having a lower dielectric index, such as an SiOC film, a PSG film, a BPSG film, an USG film, an FSG film, an HDP film, a PE-TEOS film, or an SOG film.

A first photo-resistive pattern (not shown), which defines a via hole 205, is formed on the interlayer insulating film 204. The via hole 205 is formed by etching the interlayer insulating film 204 using the first photo-resistive pattern as an etching mask. Next, an organic bottom anti-reflective coating (not shown) is applied to fill the via hole 205 up, using a spin applying method. Subsequently, a second photo-resistive pattern (not shown), which defines a trench 210, is formed on the semiconductor substrate 200. The trench 210 is formed by etching a portion of the interlayer insulating film 204 using the second photo-resistive pattern as an etching mask. Then, the second photo-resistive pattern and a residual anti-reflective coating are removed to form a dual damascene pattern.

Subsequently, a diffusion stopper film 212 is formed to stop diffusion of copper, in conformity with the whole surface of the semiconductor substrate 200 on which the dual damascene pattern consisting of the via hole 205 and the trench 210 is formed. It is possible to form the diffusion stopper film 212 out of a material film which has better adhesion to the first interlayer insulating film 204 and a metal film 214 and is capable of stopping diffusion of the metal film 214, such as a Ti film, TiN film, etc. It is desirable that the diffusion stopper film 212 is formed to the thickness of 100 to 300 Å by using a CVD method.

A metal seed layer (not shown) is formed on the diffusion stopper film 212, and then the metal film 214 is formed using an electroplating. The metal film 214 may be formed of a copper (Cu) film.

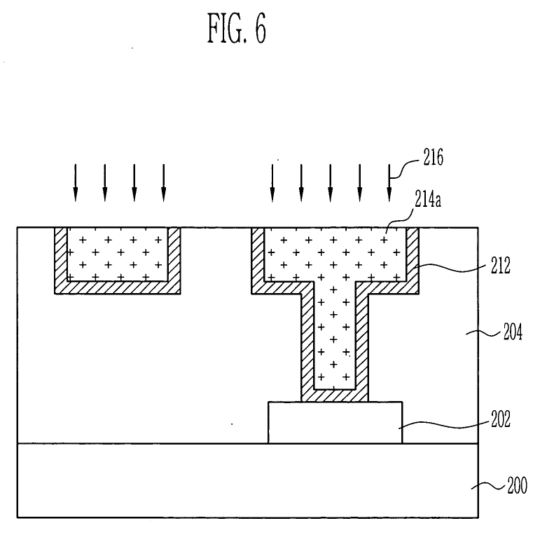

Refer to FIG. 6, a metal line 214a is formed by chemically and mechanically polishing the metal film 214. It is desirable that the chemical and mechanical polishing process is performed until the second interlayer insulating film 204 is exposed. The metal film 214 and the diffusion stopper film 212 on the top side of the second interlayer insulating film 204 are removed.

Then, as described above, an electroless electroplating 216 is performed using a titanium chloride (TiCl₄) solution or a ruthenium chloride (RuCl₃) solution. Namely, ruthenium (Ru) metal or titanium (Ti) metal is selectively formed on a surface of the copper (Cu) metal line 214a by dipping the copper (Cu) metal line into a ruthenium chloride solution or dipping the copper (Cu) metal line into a solution containing titanium chloride (TiCl₄) and hypo-phosphorous acid (H₃PO₂).

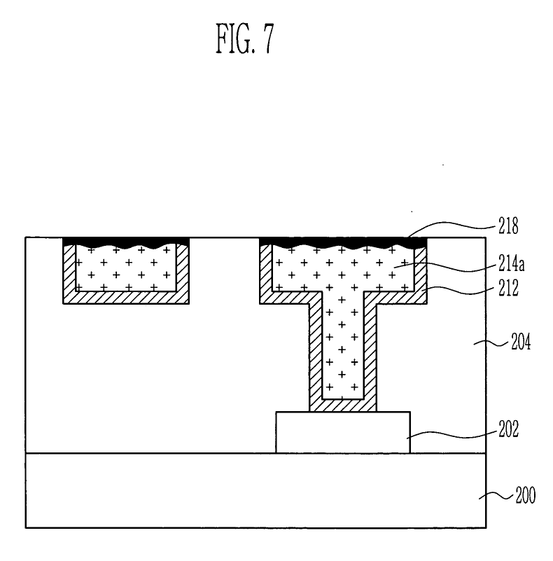

Refer to FIG. 7, titanium (Ti) or ruthenium (Ru) metals 218 is selectively formed on the metal film, e.g., only a surface of the copper (Cu) due to the electroless electroplating. As a result, it is possible to improve reliability of the copper metal line by selectively attaching titanium (Ti) or ruthenium (Ru) on only the exposed surface of the copper on which a chemical and mechanical polishing process was performed, and thus decreasing electro-migration. Ti/Cu or Ru/Cu layers are formed by coating a surface of the copper (Cu) with titanium (Ti) or ruthenium (Ru), such that resistance to electro-migration can be improved.

Titanium (Ti) or Ruthenium (Ru) metals 218 is selectively formed on the metal film 214a, and then an annealing process is performed under an atmosphere containing nitrogen (N₂), hydrogen (H₂), or argon (Ar) gases, at a temperature of 200 to 400° C., and for 1 to 3 hours.

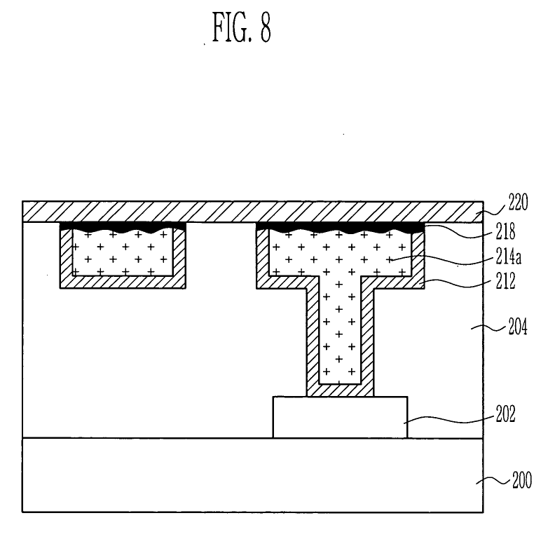

Refer to FIG. 8, a capping film 220 is formed on the whole surface of a resultant object in which titanium (Ti) or Ruthenium (Ru) metals 218 is selectively formed. The capping film 220 is formed of silicon nitride film (Si₃N₄) or silicon carbide film (SiC).

The second embodiment has been described as only an example of a method of forming a dual damascene pattern, and the present invention is not limited to the above-described embodiments. Further, it should be understood that the present invention can also be applied to various methods where a dual damascene pattern is formed to form a metal line having a trench shape and then titanium (Ti) or ruthenium (Ru) metals is selectively formed on the metal line.

According to the method of forming a metal line of a semiconductor device, it is possible to improve reliability of the copper metal line by selectively forming titanium (Ti) or ruthenium (Ru) metals on only the exposed surface of the copper on which a chemical and mechanical polishing process was performed.

Hereto, although the foregoing description has been made with reference to the preferred embodiments, the present invention is not limited to the embodiments described above and it is to be understood that changes and modifications of the present invention may be made by the ordinary skilled in the art without departing from the spirit and scope of the present invention and appended claims.

What is claimed is:

1. A method of forming a metal line of a semiconductor device, comprising the steps of:
forming an interlayer insulating film on a semiconductor substrate;
forming a metal line shaped pattern by etching the interlayer insulating film;
forming a diffusion stopper film in conformity with a whole surface of a resultant material in which the metal line shaped pattern is formed;
forming a copper film on the diffusion stopper film;
forming a copper metal line by chemically and mechanically polishing the copper film and the diffusion stopper film above the interlayer insulating film;
attaching a titanium metal or a ruthenium metal to only the copper metal line selectively; and
annealing the attached titanium metal or ruthenium metal.

2. The method according to claim 1, wherein the step of attaching the ruthenium metal is performed by dipping the copper metal line into a ruthenium chloride (RuCl₃) solution.

3. The method according to claim 1, wherein the step of attaching the titanium metal is performed by dipping the copper metal line into a solution containing titanium chloride (TiCl₄) and hypo-phosphorous acid (H₃PO₂).

4. The method according to claim 1, wherein the annealing step is performed under an atmosphere containing nitrogen (N₂), hydrogen (H₂), or argon (Ar) gases, at a temperature of 200° C. to 400° C., and for 1 to 3 hours.

5. The method according to claim 1, further comprising a step of forming a capping film after the annealing step.

6. The method according to claim 1, wherein the capping film is formed of a silicon nitride film (Si₃N₄) or a silicon carbide film (SiC).
